(19) United States
(12) Patent Application Publication
(10) Pub. No.: US 2023/0227974 A1
(43) Pub. Date: Jul. 20, 2023

(54) SUBSTRATE PROCESSING APPARATUS AND METHOD

(71) Applicant: Picosun Oy, Espoo (FI)

(72) Inventor: Marko PUDAS, Masala (FI)

(73) Assignee: Picosun Oy, Espoo (FI)

(21) Appl. No.: 18/002,512

(22) PCT Filed: Jun. 11, 2021
(86) PCT No.: PCT/FI2021/050438

§ 371 Date: Dec. 20, 2022

(30) Foreign Application Priority Data
Jun. 26, 2020 (FI) 20205683

(51) Int. Cl. C23C 16/455; C23C 16/44; C23C 16/458; C23C 16/54; H01J 37/32

(52) U.S. Cl. CPC C23C 16/45551; C23C 16/45536; C23C 16/4412; C23C 16/4584; C23C 16/45519; C23C 16/54; H01J 37/32761; H01J 37/32834; H01J 2237/20221

(57) ABSTRACT

A substrate processing apparatus, includes a reaction chamber, a central processing volume within a vertically oriented central processing portion of the reaction chamber, to expose at least one substrate to self-limiting surface reactions in the central processing volume, at least two lateral extensions in the reaction chamber laterally extending from the central processing portion, and an actuator configured to reversibly move at least one substrate between the lateral extension(s) and the central processing volume.

### FIELD

The aspects of the disclosed embodiments generally relate to substrate processing apparatus and a method. More particularly, but not exclusively, the aspects of the disclosed embodiments relate to plasma-enhanced atomic layer deposition (ALD) reactors.

### BACKGROUND

This section illustrates useful background information without admission of any technique described herein representative of the state of the art.

In chemical deposition methods, such as atomic layer deposition (ALD), plasma can be used to provide required additional energy for surface reactions. While ALD reactors have existed since many decades ago, plasma-enhanced reactors represent a younger technology. There is an ongoing need to develop improved plasma-enhanced ALD (PEALD) reactors or at least to provide alternatives to existing solutions.

### SUMMARY

The aspects of the disclosed embodiments are directed to provide an improved substrate processing apparatus or at least to provide an alternative solution to existing technology.

According to a first example aspect of the disclosed embodiments there is provided a substrate processing apparatus, comprising:

a reaction chamber;
a central processing volume within a vertically oriented central processing portion of the reaction chamber, to expose at least one substrate to self-limiting surface reactions in the central processing volume;
at least two lateral extensions in the reaction chamber laterally extending from the central processing portion; and
an actuator configured to reversibly move at least one substrate between the lateral extension(s) and the central processing volume.

In certain embodiments, the actuator is configured to reversibly move the at least one substrate between at least one lateral extension and the central processing volume (provided by the vertically oriented central processing portion).

In certain embodiments, the vertical orientation of the central processing portion means that the central processing portion is vertically longitudinal. In certain embodiments, the vertically oriented central processing portion of the reaction chamber is implemented by a reaction vessel (or by a reaction vessel assembly). In certain embodiments, the reaction vessel (or assembly) comprises a reaction chamber bowl. In certain embodiments, the reaction vessel has rotational symmetry around a vertical rotation axis. In certain embodiments, the reaction vessel (or assembly) has parts both upwards and downwards from a substrate that is in a substrate processing position. Accordingly, in certain embodiments the reaction vessel (or assembly) extends from above the substrate to below the substrate (when in processing position). In certain embodiments, the horizontal cross-section of the reaction vessel is circular (or a circle). In certain embodiments, the cross-sectional area of the reaction vessel is different at different heights of the vessel (i.e., the diameter of the circular cross-section varies depending on the point at which the cross-section is taken). In certain embodiments, the horizontal cross-section of the reaction vessel or certain parts of the reaction vessel is a polygon, for example a square.

In certain embodiments, the reaction vessel comprises a first sidewall with a first feedthrough or opening that continues as a first lateral extension. In certain embodiments, the reaction vessel comprises a second sidewall opposite to the first sidewall, having a second feedthrough or opening that continues as a second lateral extension. In certain embodiments, the reaction vessel comprises more than two feedthroughs or openings at sidewalls surrounding the reaction vessel, the feedthroughs or openings continuing as lateral extensions.

In certain embodiments, the central processing portion or the reaction vessel extends lower, compared to a bottom level of the lateral extension(s).

In certain embodiments, the central processing portion or the reaction vessel extends higher, compared to a top level of the lateral extension(s).

In certain embodiments, the at least one substrate is configured to remain stationary during the exposure to self-limiting surface reactions, while positioned in the central processing volume.

In certain embodiments, the apparatus comprises a source of energy, configured to expose the at least one substrate to additional energy in the form of plasma or radiation, in the central processing volume.

In certain embodiments, sequential self-saturating (or self-limiting) surface reactions with additional energy are performed on a substrate surface inside the central processing volume.

In certain embodiments, the reaction chamber is configured to allow a reversible transport of the at least one substrate between the lateral extension(s), and the central processing volume.

In certain embodiments, the reaction chamber is configured to allow a reversible transport of the at least one substrate between the lateral extension(s), and the central processing volume, without exposing the at least one substrate to self-limiting surface reactions while in the area of said lateral extensions.

In certain embodiments, the apparatus is configured to process a plurality of substrates, wherein the said plurality of substrates is present in the reaction chamber simultaneously.

In certain embodiments, a limited number of substrates, such as one substrate, resides during processing within the central processing volume and the remaining number of said plurality of substrates reside within the lateral extensions, while the limited number of substrates is being processed within the central processing volume.

In certain embodiments, at least 2, at least 4, or at least 9 substrates are processed within the reaction chamber simultaneously. In certain embodiments, part of the substrates is processed in a first part of the reaction chamber and another part in another part of the reaction chamber simultaneously.

In certain embodiments, the central processing portion comprises only one inlet for plasma (or plasma reactant).

In certain embodiments, the central processing portion comprises at least one inlet for plasma (or plasma reactant) and at least one inlet for another precursor (or reactant), such as a metal precursor. In certain embodiments, the central processing portion comprises a photon source, and at least one inlet for another precursor (or reactant), such as a metal precursor.

In certain embodiments, at times at which no reactive chemical enters the central processing volume, mere inert fluid flow enters the central processing volume via respective inlet(s) of the reactive chemical(s).

In certain embodiments, the apparatus is configured to expose at least one substrate in the central processing volume to additional energy while other substrates are being processed without additional energy in the lateral extension(s). Accordingly, in certain embodiments, a substrate exposed to additional energy, such as plasma or radiation in the central processing volume, is subsequently processed within a lateral extension without exposing the substrate to additional energy, such as plasma or radiation, while in the area of said lateral extension.

In certain embodiments, the processing within the lateral extension(s) comprises purging the at least one substrate surface with inert fluid.

In certain other embodiments, the processing within the lateral extension comprises exposing the at least one substrate to a (or another) precursor vapor. In certain embodiments, the processing within the lateral extension comprises exposing a substrate in the first lateral extension to different precursor vapor, than what a substrate in the second lateral extension is exposed to. In certain embodiments, the apparatus is configured to expose the substrate to at least 3 (three) different process gases or precursors during one process cycle. In certain embodiments, there are more than two lateral extensions, which can be reached, for example, by individually moved substrates. In certain embodiments, the inner volume of each lateral extension and the substrate(s) therein, can be exposed to a different precursor vapor (non-plasma gas). In certain embodiments, substrate(s) in the central processing portion is(are) exposed to a first reactant (or precursor), substrate(s) in a first lateral extension to another reactant (or precursor), and substrate(s) in a second lateral extension to yet another reactant (or precursor). In certain embodiments, the substrate(s) in the central processing portion is(are) exposed successively to a first reactant (or precursor) and to a second reactant (or precursor). In certain embodiments, the exposure to at least one of the first and second reactants comprises use of additional energy in the form of plasma (or photons).

In certain embodiments, the lateral extensions comprise fluid inlets at their distal ends. In certain embodiments, inactive or active fluid entering the lateral extension from the fluid inlets is evacuated from the reaction chamber via an exhaust connection of the central processing portion (from below the substrate or from below the substrate level). In certain embodiments, all fluid inlets in the lateral extensions are for inlet of inactive fluid only.

In certain embodiments, the lateral extensions are in fluid communication with the central processing portion. In certain embodiments, the apparatus is configured to provide a fluid flow from the lateral extensions towards the central processing portion. In certain embodiments, the central processing portion comprises flow geometry preventing, limiting, or hindering a flow from the central processing portion towards the lateral extension(s). In certain embodiments, the flow direction in the central processing portion is predominantly vertical and in the lateral extensions predominantly lateral or horizontal. In certain embodiments, the apparatus provides for a horizontal fluid flow from the lateral extensions towards the top-to-bottom oriented flow of the central processing portion.

In certain embodiments, at least two different binary ALD processes are enabled by separating the substrate processing within the central processing volume and the substrate processing within the lateral extensions, but still taking place at least partially within the same reaction chamber.

In certain embodiments, the apparatus comprises a source of additional energy, within the central processing volume or within the reaction vessel (or assembly). In certain embodiments, the source of additional energy resides on top of the substrate (while the substrate is in a processing position within the central processing volume). In certain embodiments, in case the source of additional energy is a plasma source, the plasma source comprises a plasma formation section within the central processing volume. In certain embodiments, the apparatus comprises a source of additional energy partially inside the central processing volume.

In certain embodiments, the source of additional energy is a plasma generator. In certain embodiments, the plasma generator is a remote plasma generator. In certain embodiments, the source of additional energy is a photon source, such as an ultraviolet radiation generator, or a laser light source.

In certain embodiments, the additional energy source is configured to provide the central processing volume with at least one plasma species entering the central processing volume from above. In certain embodiments, the additional energy source is configured to provide the central processing volume with two different plasma species, wherein a first plasma species is generated above the central processing volume and a second plasma species is generated remotely. In certain embodiments, self-saturating surface reactions on a substrate surface are affected by introducing gas phase chemicals and activating the chemicals to a plasma state.

In certain embodiments, the apparatus is configured to process the at least one substrate within the reaction chamber according to a process sequence comprising, or consisting of, process cycles, wherein a part of process steps in an individual process cycle is performed within the central processing volume and a remaining part within the lateral extension(s).

Accordingly, in certain embodiments a process sequence in which the position of a substrate alternates between the central processing volume and the lateral extension is provided.

In certain embodiments, the apparatus comprises the said actuator, the said actuator being configured to move at least one substrate from a first lateral extension to the central processing volume from the central processing volume to a second lateral extension, and back from the second lateral extension to the first lateral extension via the central processing volume.

In certain embodiments, the apparatus is configured to purge both the central processing volume and the lateral extensions by a single processing step. In certain embodiments, said purge is a chemical purge. In certain embodiments, the chemical herein means a non-plasma chemical or an inactive chemical. In certain embodiments, the single processing step means a purge step performed during a process cycle, or in between process cycles, or after a last process cycle in a deposition sequence, or after a completed deposition sequence.

In certain embodiments, the apparatus is configured to inlet inactive fluid or gas into the central processing volume via a precursor vapor (or plasma reactant) inlet or each precursor vapor (or plasma reactant) inlet when precursor vapor (or plasma reactant) is not inlet into the central processing volume via the inlet(s) in question. In certain embodiments, the apparatus is configured to inlet inactive fluid or gas into the lateral extension(s) via a precursor vapor inlet or each precursor vapor inlet of the lateral extension(s) when precursor vapor is not inlet into the lateral extension(s) via the inlet(s) in question.

In certain embodiments, the apparatus is configured to process the substrate in vacuum pressure. In certain embodiments, the apparatus is configured to maintain the pressure in the reaction chamber between 10 mbar and 1 μbar, between 1 mbar and 1 μbar, or between 0.1 mbar and 1 μbar during the pulses of the plasma/photon/chemical exposure period in the process cycle. In certain embodiments, the pressure is kept in between the plasma/photon/chemical pulses, between 0.5 mbar and 50 μbar. In certain embodiments, the pressure is kept between 0.5 mbar and 50 μbar, also during a purge period that follows (or is subsequent to) a plasma/photon/chemical exposure period in the process cycle. In certain embodiments, the pressure in the plasma generator is kept optimum for plasma generation, while the pressure outside the plasma generator, but inside the reaction chamber is kept lower, such as ½ or ⅕ or 1/10 or 1/100 of the plasma generator pressure.

In certain embodiments, the reaction chamber comprises at least the parts of central processing portion and at least two lateral extensions. In certain embodiments, the reaction chamber comprises more than two lateral extensions.

In certain embodiments, the apparatus comprises an outer chamber at least partly surrounding the reaction chamber.

In certain embodiments, the reaction chamber consists of the central processing portion and the lateral extensions, wherein the central processing portion comprises an upwards directed continuation and a downwards directed continuation.

In certain embodiments, the central processing volume is arranged inside the upwards directed continuation, the central processing volume thereby being a part of the reaction chamber wherein the substrate processing comprising additional energy takes place.

In certain embodiments, the apparatus comprises a narrow passage (or a constriction) at the interface between the central processing volume and the lateral extension(s). In certain embodiments, the narrow passage between the central processing volume and the lateral extension(s) has a vertical height of less than 5 mm, preferably less than 1 mm, yet more preferably less than 0.1 mm.

In certain embodiments, the apparatus comprises a top-to-bottom flow in the central processing volume and wherein exhaust of gases from the central processing volume is arranged beneath the substrate(s).

In certain other embodiments, the apparatus comprises a top-to-bottom flow in the central processing volume, which flow is at least partially diverted from the direction of vertical flow, and wherein the exhaust of gases from the central processing volume is arranged beneath the substrate(s).

In certain embodiments, the apparatus comprises a top-to-bottom flow in the central processing volume, the flow arriving to the central processing volume through multiple openings, and the flow being directed towards the substrate(s), wherein the exhaust of gases from the central processing volume is arranged beneath the substrate(s).

In certain embodiments the individual flows, arriving through multiple openings and entering the central processing volume, have uneven flow distribution in respect to one another.

In certain embodiments, the apparatus comprises a top-to-bottom flow in the central processing volume, the flow being directed towards the substrate(s), and the flow being arranged to change its pointing position during the pulse, and wherein exhaust of gases from the central processing volume is arranged beneath the substrate(s).

In certain embodiments, the central processing portion comprises an upwards directed continuation vertically extending above the lateral extension(s), enclosing the central processing volume within.

In certain embodiments, the central processing portion comprises a downwards directed continuation, vertically extending below the substrate(s) and the lateral extension(s).

In certain embodiments, the apparatus comprises an exhaust connection, extending downwards from the lower portion of the downwards directed continuation.

In certain embodiments, the apparatus comprises a vacuum pump or a vacuum pump assembly connected to the said exhaust connection. In certain embodiments, the vacuum pump or the vacuum pump assembly comprises a turbomolecular pump. In certain embodiments, the vacuum pump or the vacuum pump assembly comprises means to react or trap chemicals or chemical products (e.g. a chemical trap), including reacting chemicals arriving from the reaction chamber channeled towards the pump (assembly) with other chemical (which may have a direct feed into the trap).

In certain embodiments, the vacuum pump or vacuum pump assembly comprises a valve(s) to stop or vary the flow of chemicals towards the pump.

In certain embodiments, the reaction chamber part below the substrate(s) called downwards directed continuation, or the vacuum pump, or the vacuum pump assembly contains a fluid inlet, wherein the fluid entering from the fluid inlet is selected to be reactive with at least one of the precursors employed in the reaction chamber. In certain embodiments, the reactive fluid comprises plasma species produced outside the reaction chamber or inside the reaction chamber, but downstream of the substrate(s) within the reaction chamber.

In certain embodiments, the apparatus comprises a top-to-bottom flow in the central processing portion and wherein exhaust of gases from the central processing portion is arranged beneath the downwards directed continuation.

In certain other embodiments, the apparatus comprises a top-to-bottom flow in the central processing portion, which flow is at least partially diverted from the direction of vertical flow, and wherein the exhaust of gases from the central processing portion is arranged beneath the substrate(s).

In certain embodiments, the apparatus provides heating of the central processing portion, and in certain embodiments the apparatus provides separate heating for upwards and downwards directed continuations. In certain embodiments, the apparatus provides heating of the lateral extensions.

In certain embodiments, the apparatus comprises fluid inlets to the lateral extensions going through an intermediate space in between the reaction chamber and the outer chamber. In certain embodiments, the intermediate space is heated. In certain embodiments, the apparatus comprises at least one heater positioned in the intermediate space. In certain embodiments, the apparatus comprises at least one heater positioned within the reaction chamber.

In certain embodiments, the apparatus comprises at least one non-plasma reactant fluid inlet to the central processing portion or central processing volume going through the intermediate space. In certain embodiments, the in-feed line leading to the non-plasma reactant fluid inlet is heated in the area outside of the outer chamber. In certain embodiments, the in-feed line is heated by a heater positioned around the in-feed line. In certain embodiments, the heater around the in-feed line is insulated by a thermally insulating cover.

In certain embodiments, the height of the central processing portion of the apparatus is at least 100%, at least 200%, at least 500% or at least 1000% higher than the height of the lateral extension(s).

In certain embodiments, the height of the upwards directed continuation is at least 50% higher than the height of the lateral extension(s). In certain embodiments, the height of the upwards directed continuation is at least 100%, at least 200%, at least 500% or at least 1000% higher than the height of the lateral extension(s).

In certain embodiments, the lateral extensions extend horizontally from the central processing portion (i.e., the lateral extensions are horizontally oriented).

In certain embodiments, the horizontal width of the lateral extension(s) in substrate moving direction is greater than that of the central processing portion.

In certain embodiments, the apparatus comprises a substrate support to carry the at least one substrate. In certain embodiments the actuator is configured to actuate the substrate support, on which the substrates are supported.

In certain embodiments, the substrate support comprises a recess for a substrate. In certain embodiments, the substrate support comprising a recess for a substrate (or a respective recess for each substrate, or a recess common for a plurality of substrates) is configured to hold the substrate(s) as at least partially embedded into the substrate support. In certain embodiments, such a substrate support is configured to support the substrate(s) so that their top surface does not vertically exceed (the level of) the top surface of the substrate support.

In certain embodiments the actuator is configured to levitate the substrate support. In certain embodiments the actuator is configured to levitate the substrate support magnetically. In certain embodiments a single common substrate support carries each of the substrates within the reaction chamber. In certain other embodiments, there are a plurality of substrate supports simultaneously within the reaction chamber. In certain embodiments, the plurality of substrate supports are actuated independently from each other. In certain embodiments, each substrate has its own support, separate from supports supporting other substrates. In certain embodiments, a double-substrate support system is provided, comprising two common supports, one in each side of the central processing portion.

In certain other embodiments, the actuator is configured to move the at least one substrate without a substrate support. In such embodiments, the substrate may or may not be levitated magnetically above the actuator.

In certain other embodiments, the substrate support forms part of the actuator actuating the movement of the substrates.

In certain embodiments, the central processing volume is fitted to encase a substrate, for example a wafer, with a diameter of at least 100 mm, with a diameter of at least 200 mm, with a diameter of at least 300 mm, or with a diameter of at least 450 mm or larger.

In certain embodiments, an entire one substrate is exposed to plasma at once (upon arrival at the central processing volume, and by omitting intermediate purge steps in the central processing volume) by a plasma pulse in the central processing volume. In certain embodiments, an entire one substrate is exposed to radiation at once (upon arrival at the central processing volume, and by omitting intermediate purge steps in the central processing volume) in the central processing volume.

In certain embodiments, all substrates are exposed to plasma at once (upon arrival at the central processing volume, and by omitting intermediate purge steps in the central processing volume) by a plasma pulse in the central processing volume. In certain embodiments, all substrates are exposed to radiation at once (upon arrival at the central processing volume, and by omitting intermediate purge steps in the central processing volume) in the central processing volume.

In certain embodiments, the apparatus is configured to control the transport of the at least one substrate independently of the transport of the other substrates simultaneously residing within the reaction chamber.

In certain embodiments, the apparatus comprises a linear actuator actuating reversible linear movement of the at least one substrate.

In certain embodiments, the actuator comprises a linear motor. In certain embodiments, the linear motor is positioned on the outside of the reaction chamber.

In certain embodiments, the lateral extensions provide linear or curved track(s) for the at least one substrate. Accordingly, in certain embodiments the lateral extensions extend horizontally to substantially opposite sides of the central processing volume.

In certain embodiments, the actuator is configured to levitate the at least one substrate (without a substrate support).

In certain embodiments, the apparatus comprises a direct fluid connection from a lateral extension to the downwards directed continuation, wherein the direct fluid connection bypasses the substrate(s) from below in the central processing portion.

In certain embodiments, the apparatus comprises at least one sealed opening, to allow entry and exit of substrates into and from the reaction chamber, without exposing the reaction chamber inner volume to the surrounding intermediate space.

In certain embodiments, the reaction chamber comprises at least two or more sealed openings to allow entry and exit of substrates into and from the reaction chamber. In certain embodiments, at least one opening is positioned at the lateral extension on one side of the central processing portion and at least one opening is positioned at the lateral extension on the other (or opposite) side of the central processing portion.

In certain embodiments, both the first and the second lateral extension comprises at least one openable and sealable loading opening at its side. In certain embodiments, a loading opening is positioned at the end, which is not connected to the central processing portion, of one lateral extension, or at the ends of both lateral extensions.

In certain embodiments, the apparatus comprises a movable lid or a lid system on the top side of the central processing volume, for accessing the reaction chamber.

According to a second example aspect of the disclosed embodiments there is provided a substrate processing method, comprising:

reversibly moving at least one substrate between lateral extensions of a reaction chamber via a central processing volume, provided by a vertically oriented central processing portion of the reaction chamber; and
exposing at least one of the substrates to self-limiting surface reactions in a central processing volume of a reaction chamber.

In accordance with yet more general aspect of the disclosed embodiments there is provided a substrate processing apparatus comprising:

a reaction chamber; and
one or more features of the embodiments disclosed in the present disclosure.

In accordance with further aspects of the disclosed embodiments there are provided methods corresponding to the substrate processing apparatus aspects.

Different non-binding example aspects and embodiments have been illustrated in the foregoing. The above embodiments are used merely to explain selected aspects or steps that may be utilized in implementations of the present disclosure. Some embodiments may be presented only with reference to certain example aspects. It should be appreciated that corresponding embodiments apply to other example aspects as well. In particular, the embodiments described in the context of the first aspect are applicable to each further aspect. Any appropriate combinations of the embodiments may be formed.

### BRIEF DESCRIPTION OF THE DRAWINGS

The aspects of the disclosed embodiments will now be described, by way of example only, with reference to the accompanying drawings, in which:

FIG. 1 shows a schematic cross section of a reaction chamber of a substrate processing apparatus in accordance with certain embodiments;

FIG. 2 shows a perspective view of certain parts of the apparatus of FIG. 1 in accordance with certain embodiments; and

FIG. 3 shows certain further details of a substrate processing apparatus in accordance with certain embodiments.

### DETAILED DESCRIPTION

In the following description, Atomic Layer Deposition (ALD) technology and Atomic Layer Etching (ALE) technology are used as an example.

The basics of an ALD growth mechanism are known to a skilled person. ALD is a special chemical deposition method based on sequential introduction of at least two reactive precursor species to at least one substrate. A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. Or, as for plasma-assisted ALD, for example PEALD (plasma-enhanced atomic layer deposition) discussed herein, or for photon-assisted ALD, one or more of the deposition steps can be assisted by providing required additional energy for surface reactions through plasma or photon in-feed, respectively. Or one of the reactive precursors can be substituted by energy, leading to single precursor ALD processes. For instance, the use of photon-assisted ALD process enables the use of only one reactive chemical. Accordingly, the pulse and purge sequence may be different depending on each particular case. The deposition cycles form a timed deposition sequence that is controlled by a logic unit or a microprocessor. Thin films grown by ALD are dense, pinhole free and have uniform thickness.

As for substrate processing steps, the at least one substrate is typically exposed to temporally separated precursor pulses in a reaction vessel (or chamber) to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition), plasma-assisted ALD, for example PEALD (Plasma Enhanced Atomic Layer Deposition) and photon-assisted or photon-enhanced Atomic Layer Deposition (known also as flash enhanced ALD or photo-ALD).

However, the present disclosure is not limited to ALD technology, but it can be exploited in a wide variety of substrate processing apparatuses, for example, in Chemical Vapor Deposition (CVD) reactors, or in etching reactors, such as in Atomic Layer Etching (ALE) reactors.

The basics of an ALE etching mechanism are known to a skilled person. ALE is a technique in which material layers are removed from a surface using sequential reaction steps that are self-limiting. A typical ALE etching cycle comprises a modification step to form a reactive layer, and a removal step to take off only the reactive layer. The removal step may comprise using a plasma species, ions in particular, for the layer removal.

In context of ALD and ALE techniques, the self-limiting surface reaction means that the surface reactions on the reactive layer of the surface will stop and self-saturate when the surface reactive sites are entirely depleted.

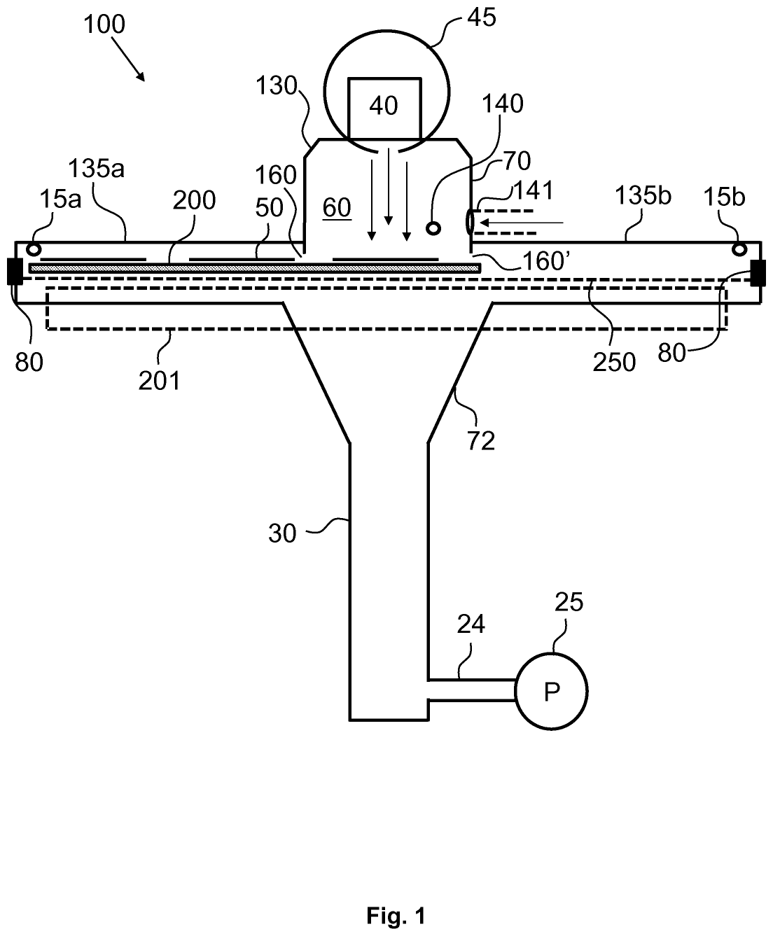

FIG. 1 shows a schematic cross section of an apparatus 100 in accordance with certain embodiments. The apparatus 100 is a substrate processing apparatus or reactor which is suitable, for instance, to perform plasma-enhanced ALD, UV-ALD deposition reactions and/or ALE etching reactions. In certain embodiments, the apparatus 100 comprises a reaction chamber 130, wherein the substrate processing reactions take place. The reaction chamber 130 comprises a centrally located central processing volume 60 for exposing at least one substrate 50 to self-limiting surface reactions in the central processing volume 60. In certain embodiments, the reaction chamber 130 comprises at least two lateral extensions 135a,135b, extending laterally from the central processing volume 60. An actuator 201, is configured to reversibly move the at least one substrate 50 along a track or route 250 between the lateral extension(s) 135 and the central processing volume 60 for substrate processing.

In certain embodiments, the at least two lateral extensions 135a, 135b extend horizontally from the central processing portion 70, 72. The at least two lateral extensions 135a, 135b can be linear or curved in the horizontal (or transverse) plane, enabling either, linear or curved movement of the substrate(s) 50 inside and along the lateral extensions 135a, 135b. In certain embodiments, there are more than two lateral extensions, extending from the central processing volume 60 to different directions, for example, but not limited to the directions in the horizontal plane, enabling a variety of substrate 50 movement arrangements during the substrate processing.

In certain embodiments, the at least two lateral extensions 135a,135b extend linearly in the horizontal plane from the opposite sides of the central processing volume 60, thereby allowing a linear movement of a substrate 50 between the first lateral extension 135a, the central processing volume 60, and the second lateral extensions 135b.

In certain other embodiments, the at least two lateral extensions 135a, 135b extend in the horizontal plane essentially from the opposite sides of the central processing portion 70,72 or extend in the horizontal plane in an angle from each other from the central processing portion 70,72. This allows a curved movement of a substrate 50, between the first lateral extension 135a, the central processing volume 60, and the second lateral extensions 135b.

In certain embodiments, the central processing portion 70,72 is vertically oriented. In certain embodiments, vertical orientation of the central processing portion 70,72 means that the central processing portion 70,72 is vertically longitudinal. In certain embodiments, the central processing portion 70,72 is implemented by a reaction vessel (or by a reaction vessel assembly). In certain embodiments, the reaction vessel (or assembly) comprises a reaction chamber bowl. In certain embodiments, the reaction vessel has rotational symmetry around a vertical rotation axis. In certain embodiments, the reaction vessel (or assembly) has parts both upwards and downwards from a substrate 50 that is in a substrate processing position. Accordingly, in certain embodiments the reaction vessel (or assembly) extends from above the substrate 50 to below the substrate (when in processing position). In certain embodiments, the horizontal cross-section of the reaction vessel is circular (or a circle). In certain embodiments, the cross-sectional area of the reaction vessel is different at different heights of the vessel (i.e., the diameter of the circular cross-section varies depending on the point at which the cross-section is taken). In certain embodiments, the horizontal cross-section of the reaction vessel or certain parts of the reaction vessel is a polygon, for example a square.

In certain embodiments, the reaction vessel comprises a first sidewall with a first feedthrough or opening 160 that continues as a first lateral extension 135a. In certain embodiments, the reaction vessel comprises a second sidewall opposite to the first sidewall, having a second feedthrough or opening 160′ that continues as a second lateral extension 135b. In certain embodiments, the reaction vessel comprises more than two feedthroughs or openings at sidewalls surrounding the reaction vessel, the feedthroughs or openings continuing as lateral extensions 135.

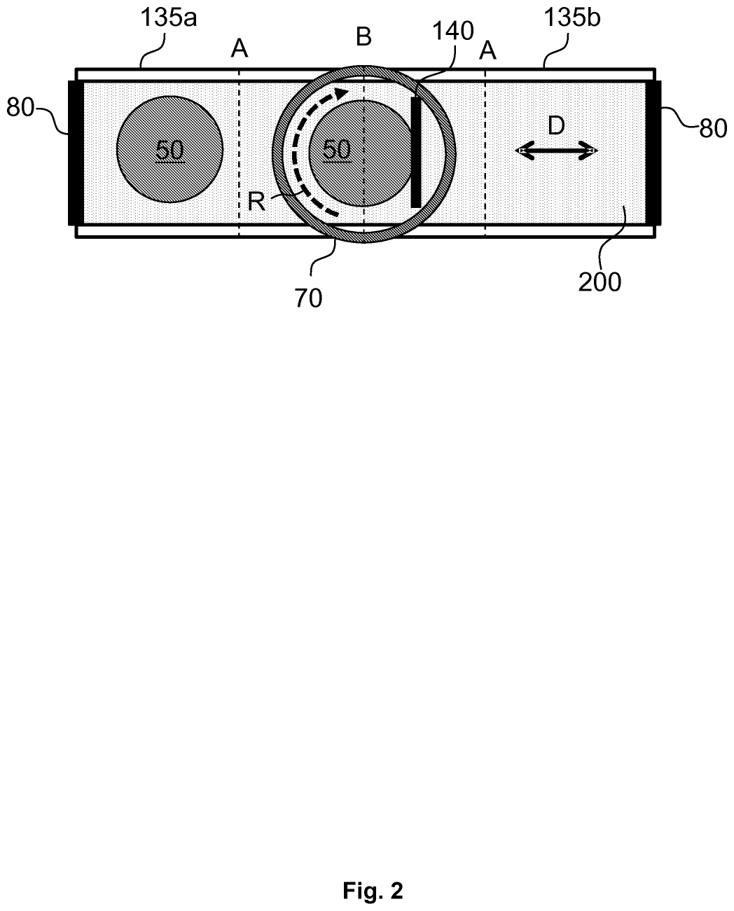

In certain embodiments, the horizontal width of a single lateral extension 135 in the substrate 50 moving direction “D”, as indicated in the FIG. 2, is greater than that of a central processing portion 70, 72, thereby allowing the accommodation and movement of more than one substrate 50 in the lateral extensions 135 simultaneously. The said width of a single lateral extension 135 in the substrate 50 moving direction is, for example, at least 100 mm to accommodate one substrate with a diameter of 100 mm in the substrate 50 moving direction. Alternatively, the width of a single lateral extension 135 in the substrate 50 moving direction, is at least 150 mm, at least 200 mm, at least 300 mm or at least 450 mm, depending on the used application, substrate size and implementation of actuators. Accordingly, the length of the lateral extension 135 in the substrate moving direction “D” may be larger, to accommodate at least one substrate 50 with a larger diameter than 100 mm. In certain embodiments, the length of a lateral extensions 135 in the substrate moving direction “D” may be such, as to accommodate at least one or more substrate(s) 50 with a diameter of at least 300 mm.

In certain embodiments, the width of a single lateral extension 135 in the substrate 50 moving direction “D” may be smaller than 100 mm, if substrates with a smaller than 100 mm diameter are employed, such as substrate cuts or substrates of other than circular shapes.

In certain embodiments, the horizontal width of the lateral extension(s) 135a, 135b in a direction “A”, as indicated in FIG. 2, that is perpendicular to the substrate 50 moving direction “D”, is narrow, to minimize the inner volume of the lateral extension 135 and the reaction chamber. The narrow distance “A” also minimizes the required volume to be purged, and the amount of fluid used for purging the lateral extension 135. In certain embodiments, the said narrow width “A” is not wider than the width of the central processing portion 70, 72 in the same plane, or the width “B” of the central processing portion 70, 72. In certain embodiments, the said width “A” is fitted to the dimeter size of the substrate 50, so that the substrate 50 has enough room to move along the lateral extension(s) 135a, 135b in the substrate moving direction “D”. In certain embodiments, the said width “A” of a lateral extension 135, may be the same or wider than substrate 50 moved therein.

In certain embodiments, the apparatus is configured to process the substrate(s) 50 continuously with fluid, while the substrates 50 reside in the area of the lateral extension(s) 135. In certain embodiments, the at least one substrate 50 undergoes self-limiting surface reactions while in the area of the central processing volume 60 (of the central processing portion) and only purging operations (with inactive gas) while in the area of the lateral extensions 135a, 135b. In certain other embodiments, the substrate(s) 50 are processed with at least two different fluids (inert fluid and process gas) while residing in the area of the lateral extension 135. In certain embodiments, the said process gas is a reactive precursor vapor used for substrate 50 processing. Accordingly, in certain embodiments part of the process steps of an individual process cycle are performed within the area of at least one lateral extension 135.

In certain embodiments, at least one fluid inlet 15a, 15b is arranged at an upper part of the lateral extension 135a, 135b, configured to target the substrates residing in the lateral extension 135 with fluid. In certain embodiments, the fluid inlet 15 is arranged in the distal end of a lateral extension 135, to reach all the substrates 50 residing in the said space. The fluid coming out of the fluid inlet 15 is configured to purge the substrates residing in the lateral extension 135 by inert gas, or to expose the substrates 50 to a process gas in other embodiments, while not being processed in the central processing volume 60. Any fluid entering a lateral extension 135 is driven by the pressure difference between the lateral extension 135 and a downwards directed continuation 72 of the reaction chamber 130, to flow towards and into the downwards directed continuation 72 and eventually pumped out of the reaction chamber 130. In certain embodiments, the flow of the fluid is configured to bypass the substrate(s) 50 from below, in the central processing portion 70,72.

In certain embodiments, the fluid inlets 15a, 15b are configured to provide the respective lateral extensions 135a 135b they open into, with different precursor vapors. The fluid inlet 15a is configured to expose the inner volume of the first lateral extension 135a and the substrate(s) 50 therein, to different precursor vapor, than what the substrate(s) 50 in the second lateral extension 135b is/are exposed to, by fluid inlet 15b. In certain embodiments, the said exposure of the substrates 50 to different precursor vapors inside the lateral extensions 135a, 135b can take place simultaneously. Furthermore, at the same time, when substrates 50 are exposed to different precursor vapors in their respective lateral extension 135a, 135b, the substrate(s) 50 residing in the central processing volume 60 is/are being processed by exposing the substrate(s) 50 to additional energy therein. In certain embodiments, the substrates are moved between the first lateral extension 135a, central processing volume 60 and to the second lateral extension 135b on a substrate support 200 in any desired sequence, to allow deposition of a plurality of different precursor layers on a single substrate 50.

For example, the fluid inlet 15a provides simultaneously the first lateral extension 135a and the substrates(s) 50 therein with precursor vapor comprising aluminum, as the fluid inlet 15b provides the second lateral extension 135b and the substrate(s) 50 therein with silicon comprising precursor vapor. Furthermore, the substrate(s) 50 simultaneously in the central processing volume 60 is/are processed with oxygen plasma. Thereby, a process cycle comprising simultaneous deposition of at least aluminum, silicon, and oxygen at different parts of the reaction chamber, can be deployed to create a desired atomic layer composition comprising these precursors on substrates 50.

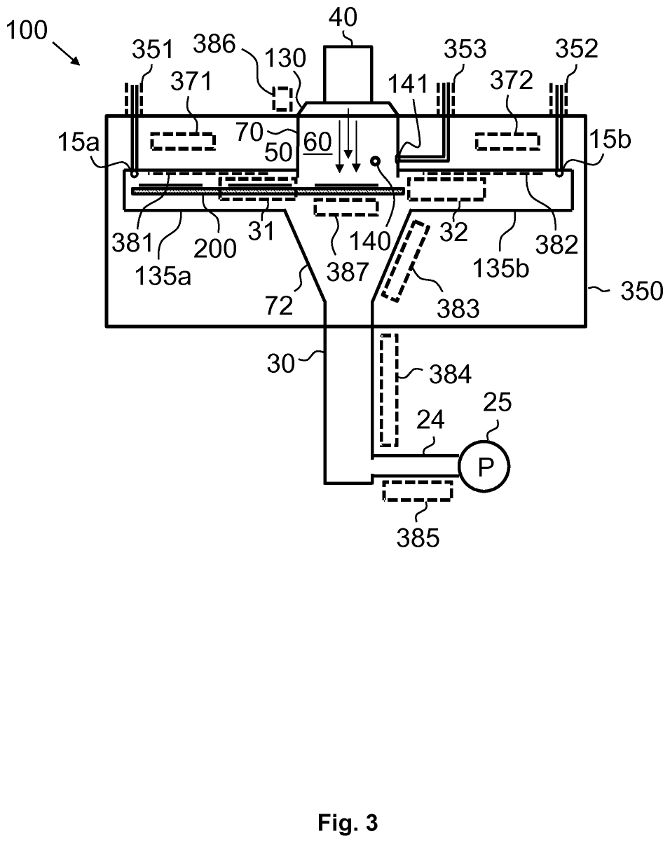

In certain embodiments, certain parts of the apparatus are heated (which will be explained later with reference to FIG. 3).

The reaction chamber 130 comprises the central processing portion 70, 72, comprising the central processing volume 60 within, for exposing the substrate(s) 50 to self-limiting surface reactions. In certain embodiments, the central processing portion comprises an upwards directed continuation 70, vertically extending above the horizontal plane of the lateral extensions 135a, 135b. The said upwards directed continuation 70 is defined by the reaction chamber 130 wall that encloses the central processing volume 60 within. In certain embodiments, the upwards directed continuation 70 may be shaped, when viewed from above, rectangular, circle or oval, the space of the central processing volume 60 being defined by the walls of the reaction chamber 130.

In certain embodiments, the central processing volume 60 is a cylindrical space, defined by the reaction chamber 130 wall. In certain other embodiments the space of the central processing volume 60 may be a space that is shaped as a truncated cone. In certain embodiments, from the horizontal perspective, the upwards directed continuation 70 rises higher in vertical direction than the lateral extensions 135a, 135b. The upwards directed continuation 70 may be at least 50% higher, than the vertical height of the lateral extensions 135 extending from the central processing portion 70,72, to optimize the distance of an energy source 40 from the substrate 50. In certain embodiments, the height of the upwards directed continuation is at least 100%, at least 200%, at least 500% or at least 1000% higher than the height of the lateral extension(s) 135.

In certain embodiments, when viewed from above (as in FIG. 2), a diameter length “B” of the central processing volume 60 is fitted to the dimeter size of the substrate 50, so that the substrate 50 has enough room to fit inside the central processing volume 60 defined by the reaction chamber 130 wall. In certain embodiments, the central processing volume is fitted to encase a substrate, with a diameter of at least 100 mm, with a diameter of at least 200 mm, with a diameter of at least 300 mm, or with a diameter of at least 450 mm or larger.

In certain embodiments, an energy source 40 is configured to provide the central processing volume 60 with additional energy, the additional energy comprising, for example, plasma or radiation/photons. In certain embodiments, the energy source 40 is placed directly above or at the side of the central processing volume 60, or inside the central processing volume 60 above the substrate. In certain embodiments, the energy source 40 is located inside at least a partially sealed volume 45 which is located at least partially inside or at the side of the central processing volume 60, which at least partially sealed volume 45 has connection means (e.g., a flow connection) to the central processing volume 60. In certain embodiments, the energy source 40 is a plasma source, wherein the plasma can be generated directly above the substrate in the central processing volume 60 by a local generator of the energy source 40. Alternatively, the plasma is generated remotely by a remote generator, which is not located within the volume 60. In certain embodiments, both local and remote plasma sources (or generators) are provided, the plasma generators being configured to provide the central processing volume 60 with two different plasma species. In certain embodiments, the energy source 40 is a photon source, such as an ultraviolet radiation generator, or a laser light generator. In certain embodiments, the energy source 40 comprises both, a photon source, and a plasma source which is separate from the photon source. In certain embodiments, the energy source 40 comprises, for instance, a monopole antenna plasma generator, a dielectric plasma generator, an inductively coupled plasma generator, or microwave electron, cyclotron or a resonance generated plasma generator. In certain embodiments, wherein the energy source 40 comprises both, a photon source and a separate plasma source, both of these energy sources are used alone or in combination in the central processing volume 60 during one process cycle.

In certain embodiments, a fluid inlet providing reactive chemical(s), to react with unreacted chemical(s) arriving upstream from the substrate(s) 50, is provided downstream from the substrate 50 in the apparatus 100. In certain embodiments, the said fluid inlet is a chemical inlet or an energy source, such as an inlet for heated gas or a plasma inlet (not shown). In certain embodiments, the said fluid inlet is located in the apparatus 100 downstream from the substrate(s) 50, but upstream from the vacuum pump (assembly) 25. For example, the said fluid inlet is located in the downwards directed continuation 72, or alternatively further downstream in an exhaust connection 30, or alternatively yet further downstream, e.g., in a pump foreline 24. For example, ejecting from the said fluid inlet heated inert gas having high temperature, such as temperature above 500° C., will induce radical or plasma species generation, which radical or plasma species will cause decomposition of unused reactive precursors.

In certain embodiments, the plasma source comprises the said plasma generator, which plasma generator comprises a plasma applicator and a power source. In certain embodiments, a power source of the plasma generator is positioned within the apparatus above the central processing volume 60. In certain embodiments, a power source of the plasma generator is positioned within the apparatus elsewhere than above the central processing volume 60. In certain embodiments, the plasma source provides a plasma formation sector within the central processing volume 60 (in its top part for example). In those embodiments, the plasma applicator (for example monopole antenna or antennas), depending on the implementation, is positioned within the volume 60. The plasma species formed by the plasma generator or applicator, flow from the plasma generator or applicator downwards towards a substrate 50. In certain embodiments, the plasma generator or the photon source is positioned above the central processing volume 60 such that the plasma/photon energy is able to target a closely defined or well-defined area such as a narrow rectangular area on a substrate 50 surface, for example in the form of a beam, while the substrate 50 is in the central processing volume 60. In certain embodiments, this area on the substrate(s) 50 changes its location on the substrate 50 surface, as the substrate 50 changes its location in the central processing volume 60, when moved in or through the central processing volume. This enables generation of surface reactions in one well-defined area of a substrate 50 surface at a time.

In certain embodiments, wherein the plasma is generated at least partially inside or at the side of the central processing volume 60, inside the at least partially sealed volume 45, the plasma can be generated in different pressure conditions than inside the central processing volume 60. For example, the pressure can be higher, such as ˜1 mbar, inside the at least partially sealed volume 45, compared to the central processing volume 60, wherein the pressure can, for example, be 0.5 mbar, more preferably 0.2 mbar, yet more preferably 0.1 mbar, and in certain processing conditions the pressure inside the central processing volume 60 can be yet lower vacuum, such as 0.01 mbar. This pressure difference drives the fluid comprising the plasma species out of the at least partially sealed volume 45, into the central processing volume 60, and towards the substrate(s) 50. In certain embodiments, the fluid flows out of the partially sealed volume 45, into the central processing volume 60, with a chocked flow effect. In certain embodiments, the at least partially sealed volume 45 has a narrow opening for the plasma to exit into the central processing volume 60, enabling a targeted chemical exposure of well-defined area on a substrate 50 surface, when moving a substrate 50 under the said narrow opening. In certain embodiments, the narrow opening of the at least partially sealed volume 45 is arranged such, that the plasma exiting the volume 45 targets a well-defined line over the substrate 50 path. The said well-defined line is a predefined narrow elongated or linear region, which may extend sideways or perpendicularly with regard to substrate movement direction “D”, thereby enabling plasma to target a cross section of the substrate 50 surface, of all the substrates 50 that pass by the plasma targeted line. In certain embodiments, the at least partially sealed volume 45 has a valve, to allow opening and closing it for substrate 50 exposure.

In certain embodiments, one or more non-plasma precursors or non-plasma chemicals (for example, non-plasma precursors and/or thermal ALD precursors, such as one or more metal precursors and/or non-metal precursor(s) and/or inactive gases) are entered into the central processing volume 60. In certain embodiments, the apparatus 100 comprises a common in-feed line or separate in-feed lines to feed these chemicals into the central processing volume 60 from above the substrate 50. In certain embodiments, the central processing volume 60 is used to expose substrates 50 to at least two temporally separate precursor chemicals. In certain embodiments, at least one chemical nozzle inlet 140 or opening 141 is implemented in the central processing volume 60, located at the wall of the upwards directed continuation 70, for example. In certain embodiments, gaseous chemical ejected from the at least one nozzle 140 or opening 141 exposes the whole upper surface or substantially the whole upper surface of a single substrate 50 in the central processing volume 60. In certain other embodiments, the gaseous chemical ejected from at least one nozzle 140 or opening 141 provides exposure only on a smaller pre-determined limited area (for example of a rectangular shape) on the substrate 50 surface (the substrate 50 may for example be moved within the central processing volume 60 and thereby experience different exposure on different surface areas). In certain embodiments, the gaseous chemical is ejected from at least two nozzles 140 or openings 141. In such embodiments, the at least two nozzles 140 or openings 141, for example, provide asynchronous exposure of the gaseous chemical at different times to surface of the substrate 50.

Although the fluid inlets 15a, 15b, the nozzle 140 and the opening 141 are shown as point sources in the schematic cross section of FIG. 1, they can also be arranged, for example, as nozzles, as pipes with holes (the pipe being oriented as indicated by the top view of nozzle 140 in the FIG. 2), or as distributors with expanding cross section, such as a cone or a triangle, thereby enabling the expansion of the fluid flow stream to match the width of the substrate 50, for example.

In certain embodiments, the central processing portion 70, 72 comprises a downwards directed continuation 72, vertically extending below the horizontal plane of the lateral extensions 135a, 135b, the said downwards directed continuation 72, being defined by the reaction chamber 130 wall. In certain embodiments, the downwards directed continuation 72 extends from the lower surface of the lateral extensions 135a, 135b downwards, forming a bowl-shaped lower portion of the central processing portion 70, 72. The downwards directed continuation 72 continues further downwards as the exhaust connection 30, for removing the chemical exhaust from the reaction chamber 130. In certain embodiments, the exhaust connection 30 extends from the lower portion of the downwards directed continuation 72 towards a vacuum pump 25 or vacuum pump assembly via an optional exhaust line or pump foreline 24 (which in an embodiment is directed to a side from a bottom section of the exhaust connection 30). In certain embodiments, the vacuum pump assembly comprises a turbomolecular pump. In certain embodiments, the vacuum pump assembly comprises also a second pump. In certain embodiments, the diameter of the exhaust connection 30 and pump foreline 24 is optimized, for a turbomolecular pump to function optimally. In certain embodiments, the vacuum pump assembly comprises means to limit or stop the flow, such as a butterfly valve or a gate valve (not shown). In certain embodiments, the operation of such valve may be synchronized with the ongoing ALD process, such as synchronization of the valve with the deposition of one chemical on all the substrates 50 simultaneously inside the reaction chamber 130 during a process cycle, or, synchronization of the valve with the deposition of one substrate 50 inside the central processing volume 60.

In certain embodiments, the apparatus is configured to provide a flow in the central processing volume 60 of the central processing portion 70,72 in top-to-bottom direction. The fluid/gaseous flow arriving from above the central processing volume 60 and/or from the at least one chemical nozzle 140 or opening 141 and/or from the lateral extension(s) 135, is configured to be exhausted into the downwards directed continuation 72 and there onwards to the exhaust connection 30, arranged beneath the substrate(s) 50.

In certain embodiments, the apparatus 100 is configured to guide the fluids entering the lateral extension(s) 135 and the central processing volume 60, into the downwards directed continuation 72 and therefrom to the exhaust connection 30, the flow direction being driven by pressure conditions created by the vacuum pump or vacuum pump assembly at the end of the exhaust connection 30 or pump foreline 24 optionally following the exhaust connection 30.

The actuator 201 is configured to cause movement of the at least one substrate 50 reversibly inside the reaction chamber 130, between the lateral extension(s) 135a,135b and the central processing volume 60. The line 250 illustrated in FIG. 1, merely represents the substrate 50 movement route or track the actuator 201 is able to cover, the actuator 201 itself being positioned either inside of the lateral extension(s) 135a, 135b, or in both, the lateral extension(s) 135a, 135b and the central processing volume 60, or elsewhere than where the route 250 is illustrated in FIG. 1. In certain embodiments, the actuator 201 extends only part of the horizontal distance of what is illustrated by the line 250 in FIG. 1. In certain other embodiments the actuator 201 is located partially inside the reaction chamber 130 and partially outside of the said reaction chamber 130. In certain other embodiments the actuator 201 is located entirely outside the reaction chamber 130. In certain embodiments, the actuator 201 comprises, for example, a linear motor, or a rotation motor located outside the reaction chamber 130 coupled with a screw bar moving the substrate support 200 within the reaction chamber.

In certain embodiments, the actuator 201 is a linear actuator. In certain other embodiments, the actuator 201 is a non-linear actuator, enabling a curved movement of the substrate(s) 50. In certain embodiments, the actuator 201 is powered by a linear motor, which may be positioned outside of the reaction chamber. In certain embodiments, the linear motor provides for a straight or a linear path. In certain other embodiments, the linear motor provides for a path other than a linear path, such as a curved path.

In certain embodiments, the actuator 201 is configured to levitate the at least one moving substrate support 200 above (a stationary part of) the actuator 201. In certain embodiments, the levitation is generated by gas flow, for example. In certain other embodiments, the actuator 201 is in physical contact with the substrate support 200. In certain embodiments, the speed of the substrate 50 movement can be modified during the movement, thereby making the process speed scalable. In certain embodiments the actuator 201 extends from a distal end of a first lateral extension 135a, through the central processing volume 60, to the distal end of a second lateral extension 135b. In certain embodiments, further actuators may be arranged inside or outside of the reaction chamber 130, to move the substrates in additional directions, such as sideways. In certain embodiments, further actuators may be arranged to move the substrate support 200 to the outside of the apparatus 100.

In certain embodiments, the substrate support 200 has means to hold the substrate 50, such as an electrostatic chuck, a recess, and/or a mechanical clamp. In certain embodiments, the substrate support 200 comprising a recess for a substrate 50 (or a respective recess for each substrate 50 or a recess common for a plurality of substrates 50) is configured to hold the substrate(s) 50 as embedded into the substrate support 200. In certain embodiments, such a substrate support 200 is configured to support the substrate(s) 50 so that their top surface does not vertically exceed (the level of) the top surface of the substrate support 200. In certain embodiments, the substrate support 200 is combined to the actuator 201.

In certain embodiments, the actuator 201 is arranged as an actuator arrangement comprising a plurality of actuators (e.g. two or more linear actuators).

In certain embodiments, the apparatus 100 comprises a substrate support 200 to give support to the substrate(s) 50 inside the reaction chamber 130. In certain embodiments, the substrate support 200 is configured to levitate with the aid of the actuator 201 for example above the actuator 201. In certain embodiments the substrate support 200 forms part of the actuator 201, the actuator 201 thereby being an assembly of parts configured to move the substrates 50. The apparatus may comprise a common substrate support 200 to support all the substrates 50 simultaneously, or more than one substrate supports 200 may reside simultaneously within the reaction chamber 130 to support individual substrates 50. In certain embodiments, more than one substrate supports 200 are moved independently from each other.

In certain embodiments, the substrate holder (or support) 200 arranged to hold a single wafer or number of wafers (or substrates), rotates around its axis as depicted by arrow R in FIG. 2. This can yet improve the uniformity of the deposition. In certain embodiments, the rotation is effected by the rotation motor comprised by the actuator (or actuator arrangement) 201. In certain embodiments, the apparatus 100 comprises an independently rotated substrate 50 or a plurality of independently rotated substrates 50. In certain embodiments, a plurality of substrates held by a single substrate support 200 rotate around their common center point. For example, a 300 mm wafer on a substrate support 200 may be replaced by three 100 mm wafers, and the wafers may be rotated by the substrate support 200 around their common center point.

In certain embodiments, the substrate support 200 is shorter than the horizontal distance from a distal end of a first lateral extension 135a to a distal end of another lateral extension 135b. In certain other embodiments, the substrate support 200 extends to support, at least part of, one substrate 50.

In certain embodiments, between the upper surface of the substrate 50, supported by the substrate support 200, and the reaction chamber 130 inner wall, a narrow passage 160, 160′ is provided at the interface between the central processing volume 60 and the lateral extension(s) 135a, 135b, enabling a barrier free entrance and exit of the substrate 50 between the said spaces of the reaction chamber 130. In certain embodiments, the narrow passage 160, 160′ has a vertical height of less than 5 mm, preferably less than 1 mm, yet more preferably less than 0.1 mm. In certain embodiments, the horizontal width of the narrow passage 160, 160′, is at least the same as the width of the substrate 50, or at least the same as the substrate support 200. The flow of fluids from the central processing volume 60 to the lateral extension(s) 135a, 135b, and vice versa, is limited, preferably minimized, or entirely prevented.

In certain embodiments at least one of the said passages 160, 160′ comprises an air knife, which directs a shower of inactive fluid/gas towards a bypassing substrate 50 from the entire width of the substrate 50 diameter or the inner width of the central processing volume 60. In certain embodiments, the air knife creates a lateral purge flow in the vicinity of the surface of the substrate 50, and also in the vicinity of the substrate support 200, thereby purging the upper surface of the substrate 50 and optionally the substrate support 200. The air knife also enables the formation of a gas curtain, which decreases or prevents the reactive fluids in the lateral extension 135 from entering the central processing volume 60 and reacting with other reactive fluids inside the central processing volume 60 in a gas phase over the substrate 50.

In certain other embodiments, a sealed intermediate volume between the lateral extension(s) 135a, 135b, and the central processing volume 60 is provided, preventing an exchange of fluids between the said two spaces of the reaction chamber 130. In certain embodiments, sealed input and output ports are arranged in the intermediate volume, enabling the intermediate volume to have different pressure conditions than the surrounding volumes.

In certain embodiments, the at least one substrate 50 is configured to enter the reaction chamber 130 through a sealed opening. Accordingly, the reaction chamber 130 comprises at least one sealed opening 80 in the reaction chamber 130 wall, to allow entry and exit of the at least one substrate 50 into and from the reaction chamber 130. In an exemplary embodiment, the sealed opening 80 is located at the distal end of a lateral extension 135a, 135b. In another exemplary embodiment, the sealed opening 80 is on the side or top surface of a lateral extension 135a, 135b. In yet another exemplary embodiment, the sealed opening is located in the reaction chamber 130 wall at the upwards directed continuation 70. In certain embodiments, there is more than one sealed opening in the reaction chamber 130. In certain embodiments, the at least one substrate 50 can enter and exit the reaction chamber 130 through any of the said possible sealed openings 80 in the reaction chamber 130 wall, including entering and exiting the reaction chamber 130 from the one and same opening 80. In certain embodiments, at least one substrate 50 can enter and exit the lateral extension 135a, 135b while another substrate 50 is being processed in the central processing volume 60.

In certain embodiments, the substrate 50 loading is enabled through the sealed openings 80 at the chamber wall surrounding the central processing volume 60 or at the lateral extension(s) 135a, 135b, with a sealed door or a gate valve, for example. The substrate 50 loading through the said sealed door or a gate valve is possible without exposing the inner reaction chamber 130 space to the surrounding intermediate space, thereby maintaining the whole, or at least part of, the reaction chamber sealed. Such direct vacuum loading entrances can be coupled to other equipment extending from the reaction chamber 130, and such entrances may be preferable when, for example, corrosive or toxic chemicals are used or produced. For example, a gate valve can be connected to the chamber wall surrounding the central processing volume 60 or to the lateral extension(s) 135a, 135b, the other side of the gate valve opening to space that is coupled to the said gate valve, thereby excluding the intermediate space from the reaction chamber 130 space. In certain embodiments, the provided means (the air knife or the sealed intermediate volume, for example) preventing the chemicals inside the central processing volume 60 from entering the lateral extension(s) 135a, 135b, also prevent relevant ALD film growth on the gate valves or the actuators 201 located in the lateral extension(s) 135a, 135b.

In certain embodiments, the apparatus 100 comprises a movable lid or a lid system on the top side of the central processing volume 60, for accessing the central processing volume 60 and the reaction chamber 130. The said lid system allows, for example, the maintenance of the reaction chamber 130. In certain embodiments, the applicator of the plasma source is contained in the lid. In certain embodiments, the power source of the plasma source is positioned elsewhere within the apparatus. In certain embodiments the lid or a lid system comprises the top side of the lateral extension(s) 135a, 135b. In certain embodiments, the lateral extension(s) 135a, 135b are openable with separate lid(s) or lid system(s).

In certain embodiments, when residing in the lateral extension 135, substrates 50 are purged with inactive fluid, while another substrate 50 is processed in the central processing volume 60. In certain other embodiments, substrates 50 are exposed to reactive precursor vapor, when residing in the lateral extension 135. In certain embodiments, the substrates 50 residing in the lateral extension(s) 135, are not exposed to self-limiting surface reactions with additional energy, such as plasma or radiation/photon energy.

In certain embodiments, the substrates 50 are exposed to self-limiting surface reactions with additional energy, for example, in the form of plasma or radiation/photon energy, in the central processing volume 60. In certain embodiments, the substrates 50 are exposed to self-limiting surface reactions one at a time inside the central processing volume 60. In certain other embodiments, more than one substrate 50 is exposed to self-limiting surface reactions inside the central processing volume 60 simultaneously, depending on the size of the substrate 50. In certain embodiments, while positioned in the central processing volume 60 the at least one substrate 50 is configured to remain stationary during the exposure to self-limiting surface reactions, enabling a high uniformity of the coating. The apparatus may be, for example, a PEALD, ALE or a UV-ALD tool (or a reactor). In certain embodiments, the substrate(s) 50 is/are exposed to a first reactive chemical in the central processing volume 60, followed by purge of the substrate(s) 50 in the lateral extension 135, which is followed by an exposure of a/the substrate(s) 50 to a second reactive chemical in the central processing volume 60, and a second purge of the substrate(s) 50 in the lateral extension 135. The said AB sequence can be more complex, ABC for example. In certain embodiments, the purge step taking place after chemical deposition can be omitted, if the chemical is deposited deploying plasma, as the plasma species decompose fast.

In certain embodiments, the apparatus is configured to actuate movement of the substrate(s) 50 reversibly between the space of the lateral extension(s) 135 and the central processing volume 60, wherein the actuating is provided by the actuator 201. In certain embodiments, the movement area of the substrate(s) 50 extends from the distal end of a first lateral extension 135a, through the central processing volume 60, to the distal end of a second lateral extension 135b, in which area, the substrate(s) 50 is configured to move reversibly and adaptively back and forth for different stages of the process cycle. The apparatus may be configured to actuate the substrate(s) 50 also into further additional lateral extension(s) 135 in a reversible manner, in which case the substrate 50 can be actuated between the said lateral extensions 135 and the central processing volume 60 reversibly in any desired actuating combination, depending on the needed process sequence.

A purge step removes the excess chemicals from the reaction chamber 130 comprising of the central processing portion 70,72 and the lateral extensions 135, which all can be purged during a single processing step, or with one and the same purge step. However, in certain embodiments, the non-plasma reactant feed into the volume 60 is not discontinued while changing the substrate 50 processed within the volume 60. Similarly, in certain embodiments, the generation of plasma species is not discontinued while changing the substrate 50 processed within the volume 60. Accordingly, in certain embodiments, a substrate change in, or into the central processing volume 60, is performed without discontinuing a reactant (or reactive vapor) feed.

In an embodiment, each substrate 50 is exposed to self-limiting surface reactions with additional energy, such as plasma, while being stationary in the central processing volume 60. After the said self-limiting surface reactions on the first substrate 50, the first substrate 50 is moved out of the central processing volume 60, and another, second substrate 50, is moved in to the central processing volume 60, without a purge step taking place in between inside the central processing volume 60. The plasma pulse used in the self-limiting surface reactions on the first substrate 50, will not have chemical contact with the surface of the second substrate 50 while the second substrate 50 waits for its turn outside of the volume 60, thereby not causing surface reactions on the second substrate 50, as the plasma species (or radicals) have a short lifespan.

In certain embodiments, each substrate 50 is exposed to self-limiting surface reactions with additional energy, such as radiation/photon energy, while being stationary in the central processing volume 60. In such embodiments, a purge step inside the central processing volume 60 between subsequent substrates 50 (and between subsequent photon exposures) is omitted.

In certain other embodiments, a substrate 50 is exposed to self-limiting surface reactions with a gaseous non-plasma e.g. metal containing chemical, while being passed through the central processing volume 60. In such embodiments, substrates 50 being passed through the volume 60 are exposed to a chemical (non-plasma reactant) in the central processing volume 60, and moved into a lateral extension 135 without performing a purge step in the central processing volume 60 therebetween (in between deposition on subsequent substrates). In certain embodiments, the at least one substrate is non-stationary during the exposure to self-limiting surface reactions, while positioned in the central processing volume 60 or in the lateral extension(s) 135a,135b. In certain embodiments, a chemical reactant shower only at a predefined narrow elongated or linear region is implemented (which may extend sideways or perpendicularly with regard to substrate movement direction “D”), for example, by the nozzle 140 or similar. In certain embodiments, the reactant shower includes plasma (or it may be replaced by another source of energy, for example radiation). The substrate 50 surface becomes processed (or deposited) while the substrate is moved through the exposing region. In such an embodiment, the whole central processing volume 60 or lateral extension 135 volume, need not be exposed to the reactant. In certain embodiments, the moving substrate 50 can be purged similarly under a purge gas shower, inside the central processing volume 60 or inside the lateral extension 135, thereby enabling a purge step which is more effective, and takes less time in each process cycle, than a conventional purge step.

FIG. 3 shows certain further details of the substrate processing apparatus 100 in accordance with certain embodiments. In certain embodiments, the apparatus comprises an outer (vacuum) chamber 350 arranged, at least partially, around the reaction chamber 130. In certain embodiments the outer chamber encloses the entire reaction chamber 130 within, whereas in some other embodiments as depicted in FIG. 3, only part of the reaction chamber 130, comprising at least the central processing portion 70,72 or part of it, is enclosed by the outer chamber.

In certain embodiments, the outer (vacuum) chamber 350 is arranged, at least partially, around the lateral extension 135a, 135b. In certain embodiments, the pressure inside the said outer chamber 350 is kept higher than inside the reaction chamber 130, to prevent chemical leakage into the intermediate space.

In certain embodiments, the apparatus comprises fluid inlets 15a, 15b to the lateral extensions 135a, 135b, respectively, going through an intermediate space in between the reaction chamber 130 and the outer chamber 350. In certain embodiments, the intermediate space is heated. In certain embodiments, the apparatus comprises at least one heater 371, 372 positioned in the intermediate space. In certain embodiments, the apparatus comprises at least one heater positioned within the reaction chamber 130 or inside the reaction chamber 130 wall (wherein the heater can form part of the reaction chamber 130 wall). In certain embodiments, the heater within the reaction chamber is positioned within the central processing portion 72 (heater 387). In certain embodiments, a heater is positioned within a lateral extension or each lateral extension 135 (heaters 381, 382). In certain embodiments, the apparatus comprises at least one non-plasma reactant nozzle 140, or opening 141 to the central processing portion 70, 72 or central processing volume 60 going through the intermediate space. In certain embodiments, the in-feed line leading to the non-plasma reactant fluid inlet is heated in the area outside of the outer chamber. In certain embodiments, the in-feed line is heated by a heater 353 positioned around the in-feed line. In certain embodiments, the heater 353 around the in-feed line is insulated by a thermally insulating cover. Similar heating implementations may be applied to in-feed lines leading to fluid inlets 15a, 15b (heaters 351, 352).

In certain embodiments, the heaters are positioned on the top side of the lateral extensions 135, the substrate(s) 50 receiving heat from above. In certain embodiments, the heaters are positioned inside the walls of the lateral extensions 135. In certain embodiments, the heaters are positioned outside the walls of the lateral extensions 135, but inside of the outer chamber enclosing the lateral extensions 135. In certain embodiments each lateral extension 135 is heated by a separate heater.

In certain embodiments, the downwards directed continuation 72 is heated by a separate heater 383. In certain embodiments, the parts 24 and 30 have their own heaters. Furthermore, any portion of the reaction chamber 130 (such as an upper part of the central processing portion 70, 72) is heater by its own heater (for example, the upper part of portion 70, 72 by heater 386) In certain embodiments, the substrate(s) 50 are heated from below in the central processing portion 70,72 by heater 387. In certain embodiments the heater 387 is for example an infrared (IR) heater. An appropriate heater type of the various heaters is selected. The heaters may be for example resistive or IR heaters.

In certain embodiments, there is at least one sealable loading opening on the side of both, the first lateral extension 135a, and/or second lateral extension 135b, depicted by loading openings 31 and 32, respectively. In certain embodiments, there is at least one sealable loading opening on the wall of the central processing volume 60 (not shown).

In certain embodiments, a sensor or a sensor port with an external sensor is arranged in the lateral extensions 135a or 135b, to measure the substrate(s) 50. The measurement can be done in the lateral extension 135, while another substrate 50 is being deposited in the central processing volume (60). For example, the temperature of the substrate and/or a deposited thickness of the coating may be measured.

Without limiting the scope and interpretation of the patent claims, certain technical effects of one or more of the example embodiments disclosed herein are listed in the following. A technical effect is increased processing speed. A further technical effect is shortening the whole substrate processing process time. For example, a linear actuator can move a substrate with a quick acceleration and high speed, thus increasing the processing speed and shortening the overall substrate processing process. A further technical effect is that the apparatus can be scaled up to a large number of substrates being processed simultaneously, the number being larger than what is presented currently in the figures. A further technical effect is ability to use plasma that is somewhat remote (i.e., non-direct plasma) due to obtained sufficient level of vacuum. A further technical effect is ability to move substrates independently from each other, even enabling loading and unloading substrate(s) while another substrate is being processed in the central processing volume. This also has the effect that it is possible to keep the narrow passage, or the air knife positioned at the narrow passage, free of substrates and substrate support(s), as the substrates are either in the central processing volume or further away in the lateral extension(s). Even closing the narrow passage with a valve is possible. A further technical effect is that a substrate can be inspected in the lateral extension(s) during the process, even while another substrate is inside the central processing volume being processed, the said inspection being enabled with an optical or electrical means, to ensure or control the process performance. A further technical effect is that during the process, more than two precursors can be sequentially introduced to each substrate, an ABCB process for example (A being a pulse phase of a first precursor, B being a pulse phase of a second precursor, C being a pulse phase of a third precursor, and phase C being followed by phase B).

The foregoing description has provided by way of non-limiting examples of particular implementations and embodiments of the present disclosure a full and informative description of the best mode presently contemplated by the inventors for carrying out the aspects of the disclosed embodiments. It is however clear to a person skilled in the art that the present disclosure is not restricted to details of the embodiments presented above, but that it can be implemented in other embodiments using equivalent means without deviating from the characteristics of the present disclosure.

Furthermore, some of the features of the above-disclosed embodiments of this present disclosure may be used to advantage without the corresponding use of other features. As such, the foregoing description should be considered as merely illustrative of the principles of the present disclosure, and not in limitation thereof. Hence, the scope of the present disclosure is only restricted by the appended patent claims.

1. A substrate processing apparatus, comprising:
a reaction chamber;
a central processing volume within a vertically oriented central processing portion of the reaction chamber, to expose at least one substrate to self-limiting surface reactions in the central processing volume;
at least two lateral extensions in the reaction chamber laterally extending from the central processing portion; and
an actuator configured to reversibly move at least one substrate between the lateral extension(s) and the central processing volume.

2. The apparatus of claim 1, wherein the at least one substrate is configured to remain stationary during the exposure to self-limiting surface reactions, while positioned in the central processing volume.

3. The apparatus of claim 1, comprising a source of energy configured to expose the at least one substrate to additional energy in the form of plasma or radiation in the central processing volume.

4. The apparatus of claim 1, configured to process the at least one substrate within the reaction chamber according to a process sequence comprising or consisting of process cycles, wherein a part of process steps in an individual process cycle is performed within the central processing volume and a remaining part within the lateral extension(s).

5. The apparatus of claim 1, comprising said actuator configured to move at least one substrate from a first lateral extension to the central processing volume, from the central processing volume to a second lateral extension, and back from the second lateral extension to the first lateral extension via the central processing volume.

6. The apparatus of claim 1, wherein the apparatus is configured to purge both the central processing volume and the lateral extensions by a single processing step.

7. The apparatus of claim 1, comprising an outer chamber at least partly surrounding the reaction chamber.

8. The apparatus of claim 1, comprising a narrow passage at the interface between the central processing volume and the lateral extension(s).

9. The apparatus of claim 1, comprising a top-to-bottom flow in the central processing volume and wherein exhaust of gases from the central processing volume is arranged beneath the substrate(s).

10. The apparatus of claim 1, wherein a central processing portion comprises an upwards directed continuation vertically extending above the lateral extensions, enclosing the central processing volume within.

11. The apparatus of claim 1, wherein the central processing portion comprises a downwards directed continuation vertically extending below the substrate(s) and the lateral extension(s).

12. The apparatus of claim 11, comprising an exhaust connection, extending downwards from a lower portion of the downwards directed continuation.

13. The apparatus of claim 11, comprising a vacuum pump or vacuum pump assembly connected to the said exhaust connection.

14. The apparatus of claim 1, wherein the height of the upwards directed continuation is at least 50% higher than the height of the lateral extension(s).

15. The apparatus of claim 1, wherein the lateral extensions extend horizontally from the central processing portion.

16. The apparatus of claim 1, wherein the horizontal width of the lateral extension(s) in substrate moving direction is greater than that of the central processing portion.

17. The apparatus of claim 1, comprising a substrate support to carry the at least one substrate.

18. The apparatus of claim 1, wherein the apparatus is configured to control the transport of the at least one substrate independently of the transport of the other substrates simultaneously residing within the reaction chamber.

19. The apparatus of claim 1, comprising a linear actuator actuating reversible linear movement of the at least one substrate.

20. The apparatus of claim 1, comprising a direct fluid connection from a lateral extension to the downwards directed continuation, wherein the direct fluid connection bypasses the substrate(s) from below in the central processing portion.

21. The apparatus of claim 1, comprising at least one sealed opening to allow entry and exit of substrates into and from the reaction chamber, without exposing a reaction chamber inner volume to a surrounding intermediate space.

22. A substrate processing method, comprising:
reversibly moving at least one substrate between lateral extensions of a reaction chamber via a central processing volume, provided by a vertically oriented central processing portion of the reaction chamber; and
exposing at least one of the substrates to self-limiting surface reactions in a central processing volume of a reaction chamber.
